(19) United States
(12) Patent Application Publication
(10) Pub. No.: US 2024/0404936 A1
(43) Pub. Date: Dec. 5, 2024

(54) STACKED STRUCTURE INCLUDING CONDUCTIVE PATTERN FOR SELF-ALIGNMENT

(71) Applicant: SAMSUNG ELECTRONICS CO., LTD., Suwon-si (KR)

(72) Inventors: Gyujin Choi, Suwon-si (KR); Dahee Kim, Suwon-si (KR); Jae-Ean Lee, Suwon-si (KR); Taehoon Lee, Suwon-si (KR)

(21) Appl. No.: 18/417,921

(22) Filed: Jan. 19, 2024

(30) Foreign Application Priority Data
Jun. 1, 2023 (KR) 10-2023-0070894

(51) Int. Cl. H01L 23/498; H01L 23/00; H01L 23/48; H01L 23/528; H01L 25/065

(52) U.S. Cl. CPC H01L 23/49838; H01L 23/481; H01L 23/49811; H01L 23/49822; H01L 23/49827; H01L 23/528; H01L 25/0657; H01L 24/16; H01L 2224/16145; H01L 2224/16227

(57) ABSTRACT

A stacked structure includes a lower substrate and a first semiconductor chip stacked on an upper surface of the lower substrate, the lower substrate includes a lower conductor pattern disposed on the upper surface of the lower substrate, the first semiconductor chip may have first and second surfaces facing each other, the second surface of the first semiconductor chip may face the upper surface of the lower substrate, and the first semiconductor chip may include a first conductor pattern disposed on the second surface. The first conductor pattern may be aligned with the lower conductor pattern in a first direction perpendicular to the upper surface of the lower substrate, and the first conductor pattern may be spaced apart from the lower conductor pattern in the first direction.

### CROSS-REFERENCE TO RELATED APPLICATIONS

This U.S. non-provisional patent application claims priority under 35 U.S.C. § 119 to Korean Patent Application No.10-2023-0070894, filed on Jun. 1, 2023, in the Korean Intellectual Property Office, the entire contents of which are hereby incorporated by reference.

### TECHNICAL FIELD

The present disclosure relates to a stacked structure including conductor patterns used for self-alignment by magnetic force.

### BACKGROUND

An assembling process on a board or a package productor that packages multiple devices includes measuring a fiducial marker formed on a substrate to determine displacement and moving a device to a corresponding coordinate through motor control to mount the device. However, in the case of large-area, thin, and composite material products, non-linearity occurs due to warpage and thermal deformation, thereby decreasing precision.

### SUMMARY

An object of the present disclosure is to provide a stacked structure including a conductor pattern for self-alignment.

The problem to be solved by the present disclosure is not limited to the above-mentioned problems, and other problems not mentioned will be clearly understood by those skilled in the art from the following description.

In general, aspects of the subject matter described in this specification can be embodied in stacked structure including: a lower substrate and a first semiconductor chip stacked on an upper surface of the lower substrate, and the lower substrate may include a lower conductor pattern disposed on the upper surface of the lower substrate. The first semiconductor chip may have first and second surfaces facing each other, and the second surface of the first semiconductor chip may face the upper surface of the lower substrate, and the first semiconductor chip may include a first conductor pattern disposed on the second surface. The first conductor pattern may be aligned with the lower conductor pattern in a first direction perpendicular to the upper surface of the lower substrate, and the first conductor pattern may be spaced apart from the lower conductor pattern in the first direction.

Another general aspect can be embodied in a stacked structure that includes: a lower semiconductor chip and a first semiconductor chip stacked on an upper surface of the lower semiconductor chip, the lower semiconductor chip may include a lower conductor pattern disposed on the upper surface, the first semiconductor chip may have first and second surfaces facing each other, and the second surface of the first semiconductor chip may face the upper surface of the lower semiconductor chip. The first semiconductor chip may include a first semiconductor substrate, second chip pads disposed on a first surface of the first semiconductor substrate, first through electrodes penetrating the first semiconductor substrate and respectively connected to the second chip pads, a first circuit layer disposed on a lower surface of the first semiconductor substrate, a first conductor pattern and first chip pads disposed on the second surface of the first semiconductor chip, and first bumps respectively disposed on the first chip pads, the first conductor pattern may be aligned with the lower conductor pattern in a first direction perpendicular to the upper surface of the lower semiconductor chip, the first conductor pattern may be spaced apart from the lower conductor pattern in the first direction, and the lower semiconductor chip and the first semiconductor chip may be connected to each other through the first bumps.

Another general aspect can be embodied in a stacked structure that includes: a lower substrate, and a semiconductor structure stacked on an upper surface of the lower substrate, the lower substrate may include a lower conductor pattern disposed on the upper surface of the lower substrate, the semiconductor structure may have upper and lower surfaces facing each other, and the lower surface of the semiconductor structure faces the upper surface of the lower substrate. The semiconductor structure may include a conductor pattern disposed on the lower surface, the conductor pattern may be aligned with the lower conductor pattern in a first direction perpendicular to the upper surface of the lower substrate, the conductor pattern may be spaced apart from the lower conductor pattern in the first direction, the conductor pattern may include a first coil pad and a second coil pad horizontally spaced apart from each other and a line portion connecting the first coil pad and the second coil pad, the line portion may have a coil shape surrounding the second coil pad, and the semiconductor structure may be a semiconductor package or a semiconductor chip.

### BRIEF DESCRIPTION OF THE DRAWINGS

FIG. 1 is a plan view of an example of a lower substrate.

FIGS. 2A to 2C are plan views illustrating a shape of a lower conductor pattern of FIG. 1.

FIG. 3 is a cross-sectional view illustrating an example of self-alignment by magnetic force when a lower substrate and a semiconductor chip.

FIGS. 4A to 4C are cross-sectional views illustrating examples of lower substrates aligned with a semiconductor chip.

FIGS. 5A to 5C are cross-sectional views illustrating examples of semiconductor chips aligned with a lower substrate.

FIGS. 6A and 6B are cross-sectional views illustrating an example of alignment of a lower substrate and semiconductor chips.

FIGS. 7A and 7B are cross-sectional views illustrating an example of alignment of semiconductor chips and chips.

FIG. 8 is a cross-sectional view of an example of a semiconductor package.

FIGS. 9A and 9B are cross-sectional views illustrating an example of alignment of a semiconductor package and a lower substrate.

### DETAILED DESCRIPTION

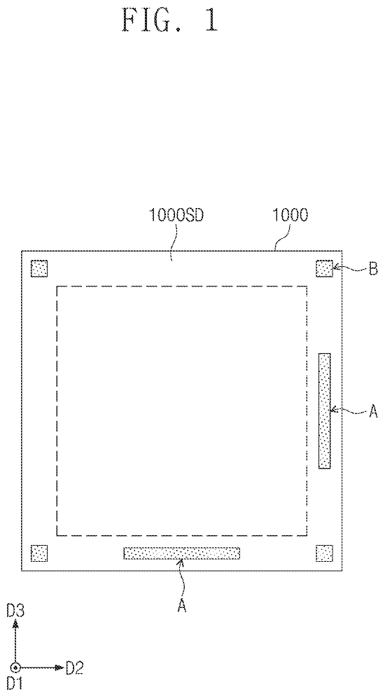

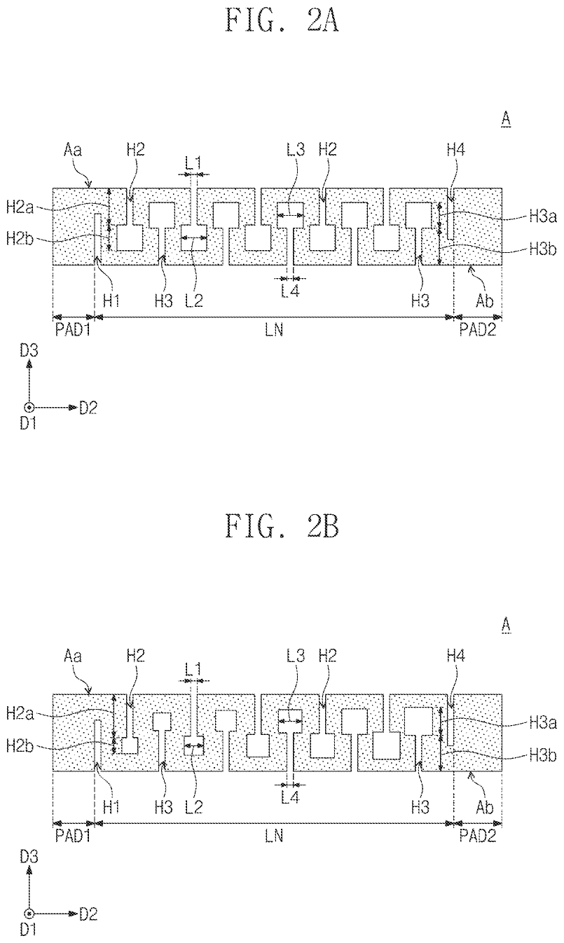

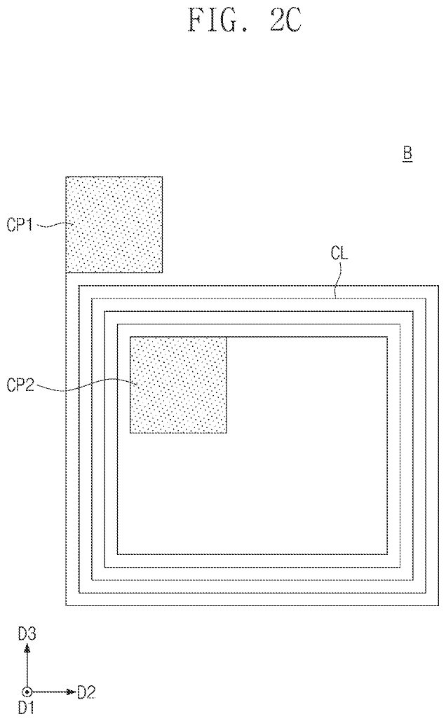

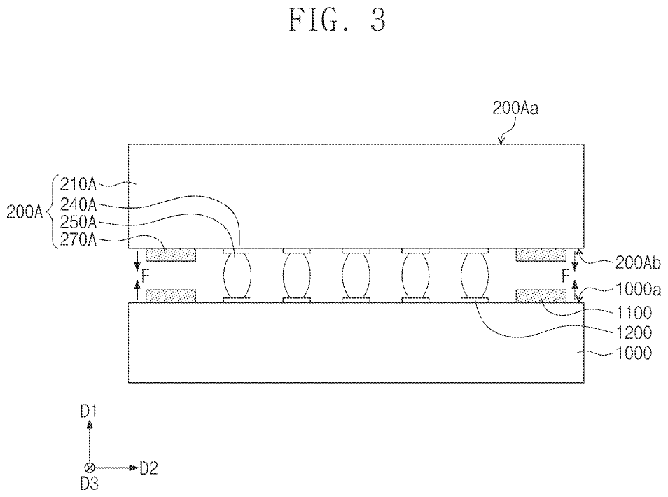

FIG. 1 is a plan view of a lower substrate. FIGS. 2A to 2C are plan views illustrating a shape of a lower conductor pattern of FIG. 1. In FIG. 1, some components are omitted for simplicity.

Referring to FIG. 1, a lower substrate 1000 may include lower conductor patterns A and B. The lower conductor patterns A and B may be disposed on a peripheral 1000SD of the lower substrate 1000. Although the example in FIG. 1 depicts both lower conductor patterns A and B disposed on a peripheral 1000SD of the lower substrate 1000, the present disclosure is not limited to what is shown. In some implementations, there is only one of the lower conductor patterns A and B.

The lower conductor patterns A and B may include metal. The lower conductor patterns A and B may include, for example, copper, aluminum, tungsten, titanium, gold, silver, or the like, or alloys thereof. A ferromagnetic material such as iron, nickel, or cobalt may be included to enhance magnetic force generated when current is applied.

Referring to FIGS. 2A and 2B, the first lower conductor pattern A may have a meander-shape, an undulating shape, zigzag shape, or the like. In detail, the first lower conductor pattern A has a first pad portion PAD1 and a second pad portion PAD2 spaced apart from each other in a second direction D2 parallel to the upper surface of the lower substrate 1000 and includes a line portion LN extending in the second direction D2 between the first pad portion PAD1 and the second pad portion PAD2. The line portion LN may extend in a zigzag shape in a third direction D3 parallel to the upper surface of the lower substrate 1000 and crossing the second direction D2. The line portion LN may have a first side surface Aa and a second side surface Ab that face each other along the third direction D3. The line portion LN may include second holes H2 and a fourth hole H4 having a bar shape extending from the first side surface Aa to the second side surface Ab and may include a first hole H1 and third holes H3 having a bar shape extending from the second side surface Ab to the first side surface Aa. The second holes H2 and the third holes H3 may be alternately disposed in the second direction D2. The second holes H2 may have a first portion H2a adjacent to the first side surface Aa and a second portion H2b adjacent to the second side surface Ab of the line portion LN, and the third holes H3 may have a third portion H3a adjacent to the first side surface Aa and a fourth portion H3b adjacent to the second side surface Ab of the line portion LN. The first portion H2a and the second portion H2b of the second holes H2 may each have a first width L1 and a second width L2 in the second direction D2, and the third portion H3a and the fourth portion H3b of the third holes H3 may each have a third width L3 and a fourth width L4 in the second direction D2. The second holes H2 may have a shape in which the first width L1 is smaller than the second width L2, and the third holes H3 may have a shape in which the third width L3 is greater than the fourth width L4. For example, referring to FIG. 2A, the second width L2 of the second holes H2 and the third width L3 of the third holes H3 may be kept constant in the second direction D2. As another example, referring to FIG. 2B, the second width L2 of the second holes H2 and the third width L3 of the third holes H3 may increase in the second direction D2. That is, a pitch of the lower conductor pattern A may increase in the second direction D2. However, the pitch and shape of the lower conductor pattern A is not limited to the illustrated in FIGS. 2A and 2B. In addition, the lower conductor pattern A may have a shape extending in the third direction D3 instead of the second direction D2.

When a current is applied to the lower conductor pattern A, a magnetic field may be generated, and accordingly, chips on which the lower conductor patterns are formed or the chip and the substrate may be self-aligned with each other due to a magnetic force applied therebetween. As illustrated in FIG. 2B, in the case of the lower conductor patterns A having different pitches, when a current is applied to the lower conductor patterns A, a strength of a magnetic field may be different, and thus the chips on which the lower conductor patterns are formed or the chip and the substrate may be self-aligned with each other in a sliding manner due to a magnetic force differently applied therebetween.

Referring to FIG. 2C, the lower conductor pattern B may have a coil shape. As illustrated, for example, the coil shape can include a square spiral with right angle turns. In detail, the lower conductor pattern B may include a first coil pad CP1 and a second coil pad CP2 spaced apart from each other in the second direction D2 and the third direction D3, and may include a line portion CL connecting the first coil pad CP1 and the second coil pad CP2. The line portion CL may be disposed to surround the second coil pad CP2 when viewed in a plan view. When a current is applied through the first coil pad CP1 and the second coil pad CP2, a magnetic field may be formed at a center of the lower conductor pattern B, and thus the chips on which the lower conductor patterns B are formed or the chip and the substrate may be self-aligned with each other due to a magnetic force applied therebetween. However, the shape of the lower conductor pattern B may have a shape different from that described above without being limited to the illustrated in FIG. 2C.

According to the present disclosure described above, the chips on which the lower conductor patterns A and B are formed or the chip and the substrate may be self-aligned with each other due to the magnetic force. Accordingly, a separate optical measurement step is unnecessary, and warpage or nonlinear deformation due to thermal deformation may be prevented even in the case of large-area, thin, composite products.

FIG. 3 is a cross-sectional view illustrating an example of self-alignment by magnetic force when a lower substrate and a semiconductor chip are stacked. For simplicity of description, descriptions overlapping those described with reference to FIGS. 1 to 2C are omitted.

Referring to FIG. 3, lower conductor patterns 1100 and first substrate pads 1200 may be provided on an upper surface 1000a of a lower substrate 1000. Although not shown, the lower conductor patterns 1100 may be electrically connected to external terminals, through which current may be applied to the lower conductor patterns 1100.

A first semiconductor chip 200A which is stacked on the upper surface 1000a of the lower substrate 1000 in a first direction D1 perpendicular to the upper surface 1000a of the lower substrate 1000 may be provided. The first semiconductor chip 200A may have a first surface 200Aa and a second surface 200Ab that face each other in the first direction D1, and the second surface 200Ab of the first semiconductor chip 200A may face the upper surface 1000a of the lower substrate 1000. First conductor patterns 270A may be disposed on the second surface 200Ab of the first semiconductor chip 200A. Although not shown, the first conductor patterns 270A may be electrically connected to external terminals, through which current may be applied to the first conductor patterns 270A. A current may be applied to the lower conductor patterns 1100 and the first conductor patterns 270A to generate a magnetic field, and accordingly, the lower conductor patterns 1100 and the first conductor patterns 270A may be aligned with each other in the first direction D1 by magnetic force. When the first conductor patterns 270A are aligned with the lower conductor patterns 1100, the first conductor patterns 270A may be spaced apart from the lower conductor patterns 1100 in the first direction D1.

The lower conductor patterns 1100 and the first conductor patterns 270A may have substantially the same shape as the lower conductor patterns A and B described above with reference to FIGS. 2A to 2C. However, the present disclosure is not limited thereto, and the lower conductor patterns 1100 and the first conductor patterns 270A may have shapes different from those described above.

The first semiconductor chip 200A may include a first semiconductor substrate 210A, the aforementioned first conductor pattern 270A, first chip pads 240A disposed on the second surface 200Ab of the first semiconductor chip 200A, and first bumps 250A respectively disposed on the first chip pads 240A. The first bumps 250A may be respectively connected to the first substrate pads 1200 of the lower substrate 1000. The first semiconductor chip 200A may be electrically connected to the lower substrate 1000 through first chip pads 240A, first bumps 250A, and first substrate pads 1200.

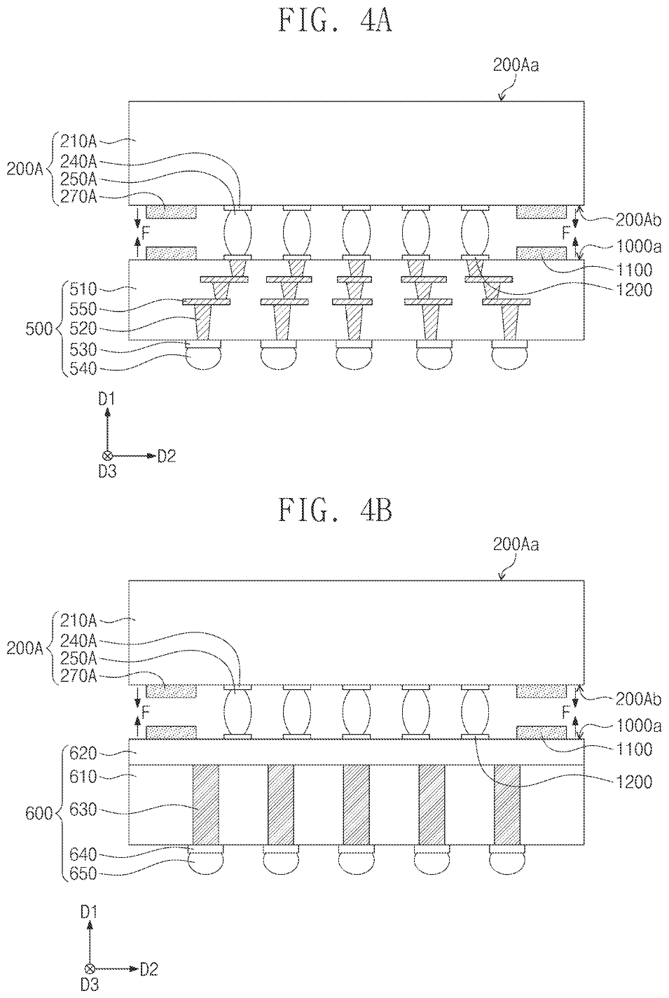

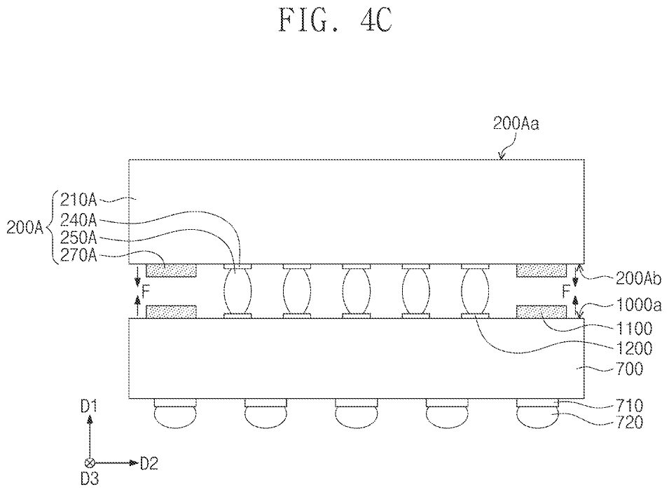

FIGS. 4A to 4C are cross-sectional views illustrating lower substrates aligned with a semiconductor chip. For simplicity of description, descriptions overlapping with those described above are omitted.

Referring to FIG. 4A, the lower substrate 1000 described with reference to FIG. 3 may be a redistribution substrate 500. The first semiconductor chip 200A may be stacked on an upper surface 1000a of the redistribution substrate 500. The upper surface 1000a of the redistribution substrate 500 may correspond to the upper surface 1000a of the lower substrate 1000 described with reference to FIG. 3. The redistribution substrate 500 may include a redistribution insulating layer 510, redistribution patterns 520 disposed in the redistribution insulating layer 510, first redistribution pads 550 and second redistribution pads 530 connected to the redistribution patterns 520, and redistribution bumps 540 each disposed on the second redistribution pads 530.

The redistribution patterns 520 may include a metal such as copper, aluminum, titanium, or tungsten, and the redistribution insulating layer 510 may include a photo-imageable dielectric material. The first and second redistribution pads 550 and 530 may be electrically connected to corresponding redistribution patterns 520. The first and second redistribution pads 550 and 530 may include a conductive material (e.g., metal). The redistribution bumps 540 may include a conductive material (e.g., metal) and may have a shape of at least one of a solder ball, a bump, and a pillar.

The lower conductor patterns 1100 and the first substrate pads 1200 may be disposed on the upper surface 1000a of the redistribution substrate 500. The lower conductor patterns 1100 may be aligned with the first conductor patterns 270A of the first semiconductor chip 200A in the first direction D1 by the magnetic force F. When the first conductor patterns 270A are aligned with the lower conductor patterns 1100, the first conductor patterns 270A may be spaced apart from the lower conductor patterns 1100 in the first direction D1. The first bumps 250A of the first semiconductor chip 200A may be respectively connected to the first substrate pads 1200. The first semiconductor chip 200A may be electrically connected to the redistribution substrate 500 through first chip pads 240A, first bumps 250A, and first substrate pads 1200.

Referring to FIG. 4B, the lower substrate 1000 described with reference to FIG. 3 may be an interposer substrate 600. The first semiconductor chip 200A may be stacked on the upper surface 1000a of the interposer substrate 600. The upper surface 1000a of the interposer substrate 600 may correspond to the upper surface 1000a of the lower substrate 1000 described with reference to FIG. 3. The interposer substrate 600 may include a first base substrate 610, a wiring layer 620 on the first base substrate 610, first substrate pads 1200 on the wiring layer 620, a plurality of through electrodes 630 penetrating the first base substrate 610, second substrate pads 640 respectively connected to the plurality of through electrodes 630, and first base bumps 650 respectively disposed on the second substrate pads 640.

The first base substrate 610 may be, for example, a silicon substrate.

The plurality of through electrodes 630 may be horizontally spaced apart from each other within the first base substrate 610. The plurality of through electrodes 630 may include, for example, a metal such as copper. The wiring layer 620 may be adjacent to the upper surface 1000a of the interposer substrate 600 and may include metal patterns electrically connected to the plurality of through electrodes 630. The first substrate pads 1200 may be disposed on the upper surface 1000a of the interposer substrate 600 and may be electrically connected to the metal patterns in the wiring layer 620. The second substrate pads 640 may be disposed on a lower surface of the first base substrate 610. The second substrate pads 640 may be electrically connected to the through electrodes 630, respectively. The second substrate pads 640 may include a conductive material (e.g., metal). The first base bumps 650 may include a conductive material (e.g., metal) and may have a shape of at least one of a solder ball, a bump, and a pillar.

The lower conductor patterns 1100 and the first substrate pads 1200 may be disposed on the upper surface 1000a of the interposer substrate 600. The lower conductor patterns 1100 may be aligned with the first conductor patterns 270A of the first semiconductor chip 200A in the first direction D1 by the magnetic force F. When the first conductor patterns 270A are aligned with the lower conductor patterns 1100, the first conductor patterns 270A may be spaced apart from the lower conductor patterns 1100 in the first direction D1. The first bumps 250A of the first semiconductor chip 200A may be respectively connected to the first substrate pads 1200. The first semiconductor chip 200A may be electrically connected to the interposer substrate 600 through first chip pads 240A, first bumps 250A, and first substrate pads 1200.

Referring to FIG. 4C, the lower substrate 1000 described with reference to FIG. 3 may be a printed circuit board. The first semiconductor chip 200A may be stacked on the upper surface 1000a of the second base substrate 700. The upper surface 1000a of the second base substrate 700 may correspond to the upper surface 1000a of the lower substrate 1000 described with reference to FIG. 3. The printed circuit board may include a second base substrate 700, third substrate pads 710 disposed on the lower surface of the second base substrate 700, and second base bumps 720 respectively disposed on the third substrate pads 710.

The third substrate pads 710 may include a conductive material (e.g., metal). The second base bumps 720 may include a conductive material (e.g., metal) and may have a shape of at least one of a solder ball, a bump, and a pillar.

The lower conductor patterns 1100 and the first substrate pads 1200 may be disposed on the upper surface 1000a of the second base substrate 700. The lower conductor patterns 1100 may be aligned with the first conductor patterns 270A of the first semiconductor chip 200A in the first direction D1 by the magnetic force F. When the first conductor patterns 270A are aligned with the lower conductor patterns 1100, the first conductor patterns 270A may be spaced apart from the lower conductor patterns 1100 in the first direction D1. The first bumps 250A of the first semiconductor chip 200A may be respectively connected to the first substrate pads 1200. The first semiconductor chip 200A may be electrically connected to the printed circuit board through first chip pads 240A, first bumps 250A, and first substrate pads 1200.

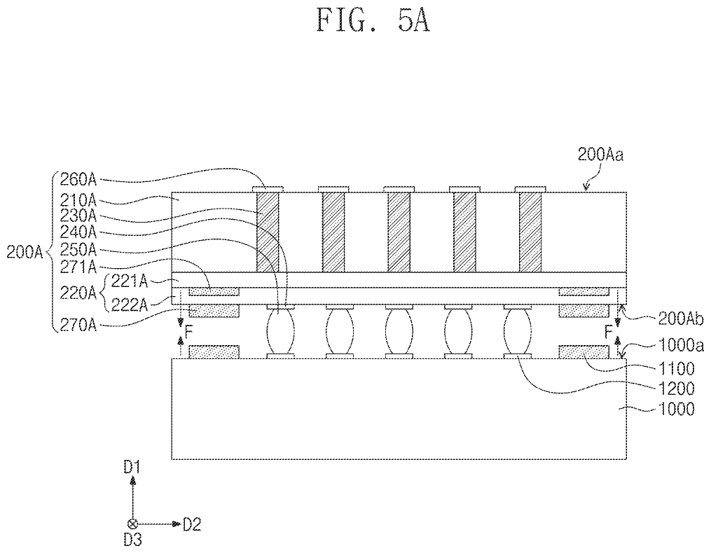

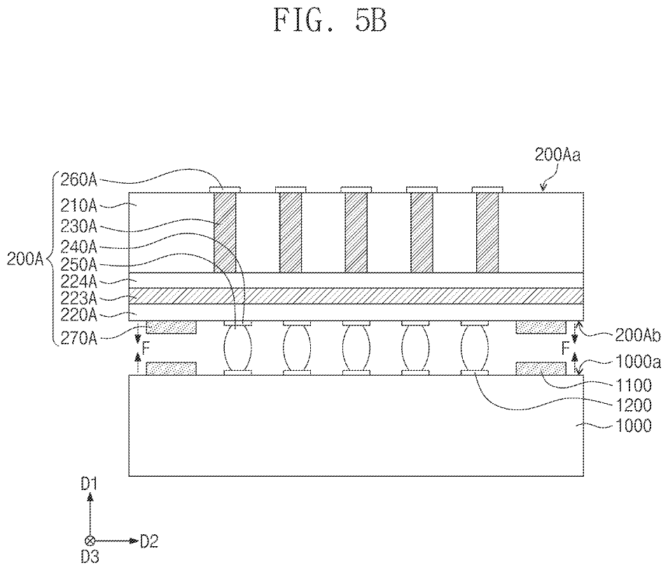

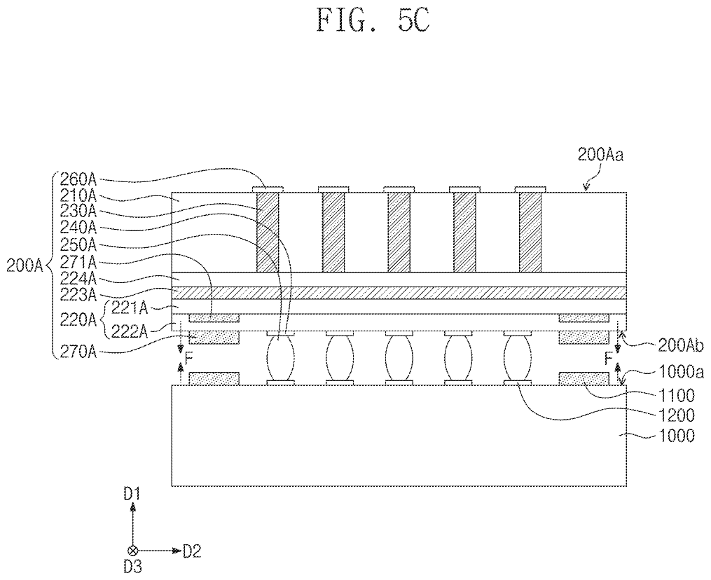

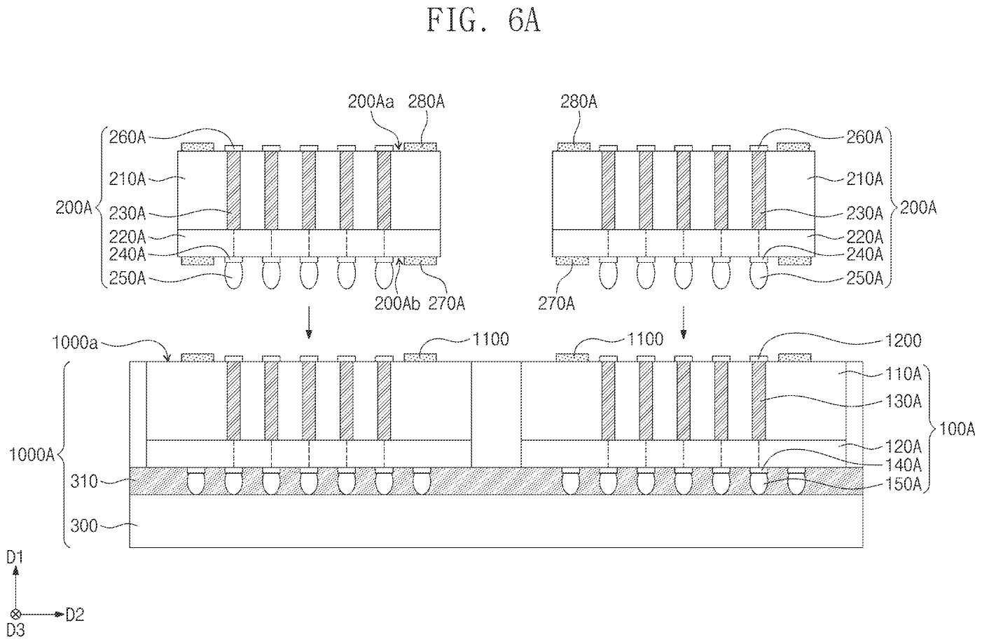

FIGS. 5A to 5C are cross-sectional views illustrating examples of semiconductor chips aligned with a lower substrate. For simplicity of description, descriptions overlapping with those described above are omitted.

Referring to FIG. 5A, a first semiconductor chip 200A may include a first semiconductor substrate 210A, a first circuit layer 220A, first through electrodes 230A, first chip pads 240A, second chip pads 260A, and first bumps 250A. The first semiconductor substrate 210A may be a silicon substrate, a germanium substrate, and/or a silicon-germanium substrate. The first circuit layer 220A may include integrated circuits formed on the first semiconductor substrate 210A.

The first through electrodes 230A may pass through the first semiconductor substrate 210A and may be horizontally spaced apart from each other within the first semiconductor substrate 210A. The first through electrodes 230A may be spaced apart from each other in the second direction D2 and may be electrically connected to the first circuit layer 220A. The first through electrodes 230A may include metal (e.g., copper, tungsten, titanium, tantalum, etc.).

The first chip pads 240A may be disposed on a second surface 200Ab of the first semiconductor chip 200A and may be electrically connected to the first circuit layer 220A. The first bumps 250A may be respectively disposed on the first chip pads 240A and may be respectively connected to the first chip pads 240A. The second chip pads 260A may be disposed on a first surface 200Aa of the first semiconductor chip 200A and may be respectively connected to the first through electrodes 230A. The first and second chip pads 240A and 260A may include metal (e.g., copper). The first bumps 250A may include a conductive material and may have a shape of at least one of a solder ball, a bump, and a pillar.

The first circuit layer 220A may include a first sub-circuit layer 221A and a second sub-circuit layer 222A. A sub-conductor pattern 271A may be disposed on a lower surface of the first sub-circuit layer 221A. Although not shown, the sub-conductor pattern 271A may be electrically connected to external terminals and a current may be applied to the sub-conductor pattern 271A. The sub conductor pattern 271A may have substantially the same shape as the lower conductor patterns A and B described with reference to FIGS. 2A to 2C. The first conductor pattern 270A and the sub-conductor pattern 271A may be included to form a greater magnetic force compared to a case where only the first conductor pattern 270A exists, and accordingly, the first semiconductor chips 200A may be more easily driven and aligned with each other.

Referring to FIG. 5B, the first semiconductor chip 200A may include an interlayer circuit layer 224A disposed on the lower surface of the first semiconductor substrate 210A. A first circuit layer 220A may be disposed on a lower surface of the interlayer circuit layer 224A, and a shielding layer 223A may be interposed between the interlayer circuit layer 224A and the first circuit layer 220A. The shielding layer 223A may include, for example, gold (Au), silver (Ag), copper (Cu), titanium (Ti), tungsten (W), iron (Fe), or tin (Sn). In a process of aligning the first semiconductor chip 200A and the lower substrate 1000 by the magnetic force between the first conductor pattern 270A and the lower conductor pattern 1100, the shielding layer 223A may serve to prevent damage to the semiconductor device caused by the magnetic force.

Referring to FIG. 5C, a semiconductor device may include an interlayer circuit layer 224A disposed on a lower surface of a first semiconductor substrate 210A, and may further include a first circuit layer 220A disposed on a lower surface of the interlayer circuit layer 224A, and a shielding layer 223A interposed between the interlayer circuit layer 224A and the first circuit layer 220A. The first circuit layer 220A may include a first sub-circuit layer 221A and a second sub-circuit layer 222A, and a sub-conductor pattern 271A may be disposed on a lower surface of the first sub-circuit layer 221A. In other words, the characteristic components of FIGS. 5A and 5B may be included together.

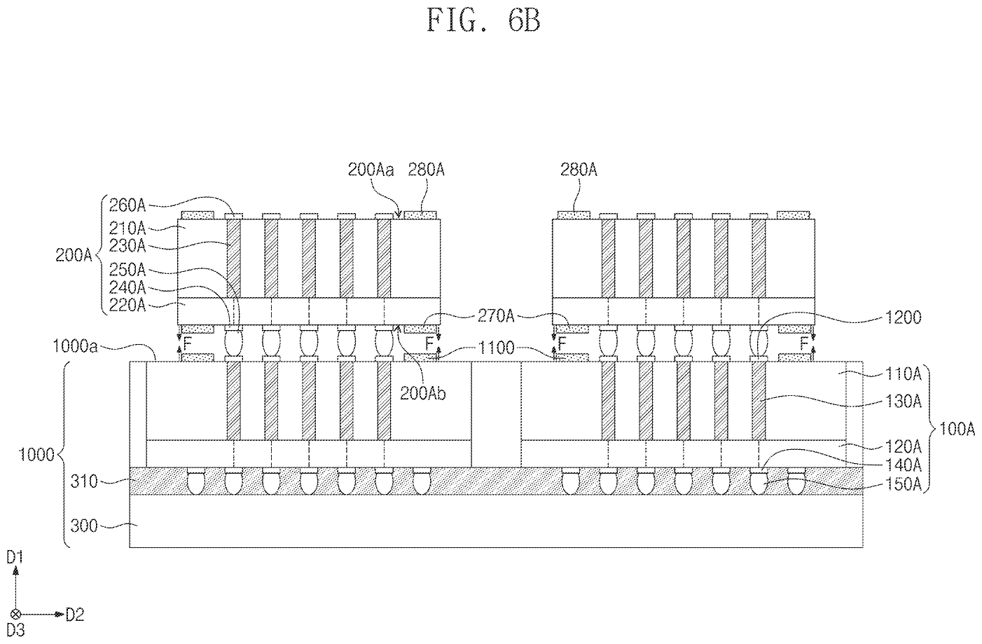

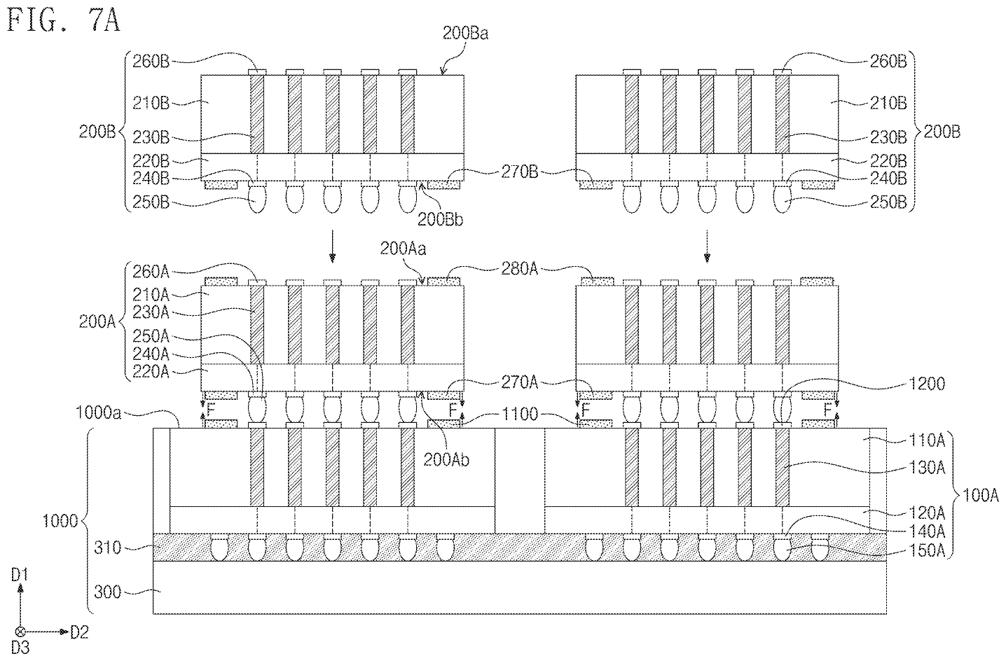

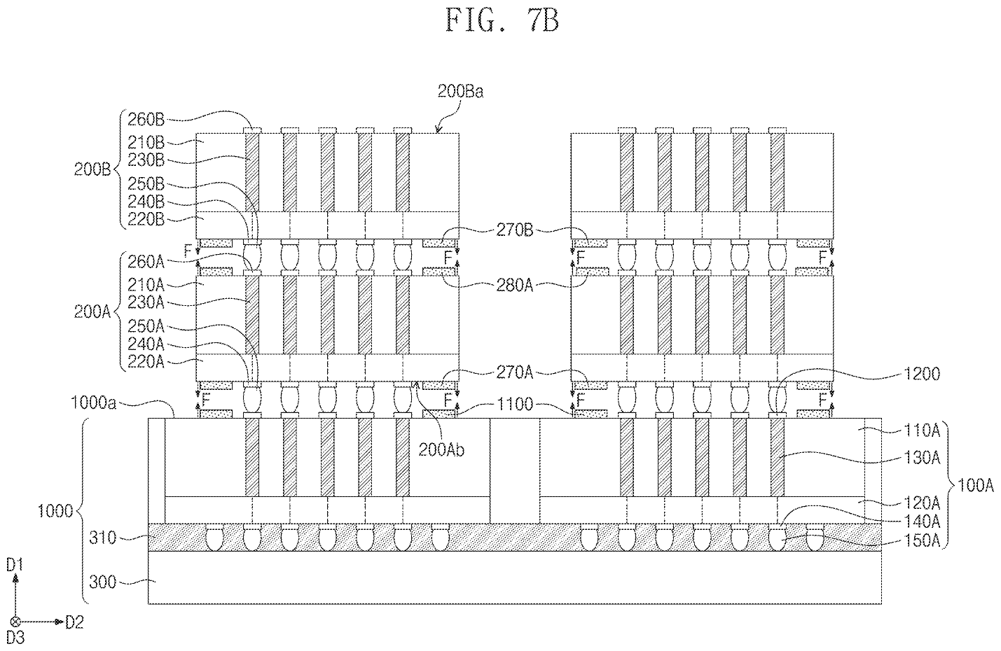

FIGS. 6A and 6B are cross-sectional views illustrating alignment of a lower substrate and semiconductor chips. FIGS. 7A and 7B are cross-sectional views illustrating alignment of semiconductor chips and chips. For simplicity of description, descriptions overlapping with those described above will be omitted.

Referring to FIG. 6A, a lower substrate 1000 may include a plurality of lower semiconductor chips 100A. A first semiconductor chip 200A may be stacked on the lower semiconductor chip 100A in a first direction D1 perpendicular to an upper surface of the lower semiconductor chip 100A. The first semiconductor chip 200A may be substantially the same as that described with reference to FIGS. 5A to 5C.

The lower semiconductor chip 100A may include a lower semiconductor substrate 110A, a lower circuit layer 120A, lower through electrodes 130A, lower chip pads 140A, and lower bumps 150A. The lower semiconductor substrate 110A may be a silicon substrate, a germanium substrate, and/or a silicon-germanium substrate. The lower circuit layer 120A may include integrated circuits formed on the lower semiconductor substrate 110A.

The lower through electrodes 130A may pass through the lower semiconductor substrate 110A and may be horizontally spaced apart from each other within the lower semiconductor substrate 110A. The lower through electrodes 130A may be spaced apart from each other in a second direction D2 parallel to the upper surface of the lower semiconductor chip 100A. The lower through electrodes 130A may be electrically connected to the lower circuit layer 120A. The lower through electrodes 130A may include metal (e.g., copper, tungsten, titanium, tantalum, etc.).

The lower chip pads 140A may be disposed on a lower surface of the lower semiconductor chip 100A and may be electrically connected to the lower circuit layer 120A. The lower bumps 150A may be respectively disposed on the lower chip pads 140A and may be respectively connected to the lower chip pads 140A. The lower bumps 150A may be connected to external terminals. The first substrate pads 1200 may be disposed on the upper surface of the lower semiconductor chip 100A and may be respectively connected to the lower through electrodes 130A. The lower chip pads 140A may include metal (e.g., copper). The lower bumps 150A may include a conductive material and may have a shape of at least one of a solder ball, a bump, and a pillar.

A lower conductor pattern 1100 may be disposed on an upper surface of the lower semiconductor chip 100A. The lower conductor pattern 1100 may have the shape of the lower conductor patterns A and B described above with reference to FIGS. 2A to 2C. Although not shown, the lower conductor pattern 1100 may be electrically connected to external terminals and a current may be applied to the lower conductor pattern 1100.

The lower semiconductor chips 100A may be provided on a carrier substrate 300. An adhesive layer 310 may be provided between the lower surface of the lower semiconductor chip 100A and the carrier substrate 300 and may be interposed between the lower bumps 150A. The lower semiconductor chips 100A may be attached to the carrier substrate 300 by the adhesive layer 310.

Referring to FIG. 6B, as described above with reference to FIG. 3, the first conductor patterns 270A and the lower conductor patterns 1100 may be aligned in the first direction D1 by magnetic force, and the first semiconductor chips 200A may be stacked on the lower semiconductor chips 100A. The first semiconductor chips 200A and the lower semiconductor chips 100A may be electrically connected through the first bumps 250A.

Referring to FIGS. 7A and 7B, second semiconductor chips 200B may be stacked on the first semiconductor chips 200A in the first direction D1, respectively.

The first semiconductor chips 200A may include upper conductor patterns 280A and second chip pads 260A disposed on a first surface Aa of the first semiconductor chip 200A.

The upper conductor patterns 280A may have substantially the same shape as the lower conductor patterns A and B described with reference to FIGS. 2A to 2C. Although not shown, the upper conductor pattern 280A may be electrically connected to external terminals and a current may be applied to the upper conductor pattern 280A.

Each of the second semiconductor chips 200B may have a third surface 200Ba and a fourth surface 200Bb that face each other. Each of the second semiconductor chips 200B may be provided so that each of the fourth surfaces 200Bb of the second semiconductor chips 200B face each of the first surfaces 200Aa of the first semiconductor chips 200A. Each of the second semiconductor chips 200B may include a second semiconductor substrate 210B, a second circuit layer 220B, second through electrodes 230B, third chip pads 240B, fourth chip pads 260B, second conductor patterns 270B, and second bumps 250B. The second semiconductor substrate 210B may be a silicon substrate, a germanium substrate, and/or a silicon-germanium substrate. The second circuit layer 220B may include integrated circuits formed on the second semiconductor substrate 210B.

The second through electrodes 230B may pass through the second semiconductor substrate 210B and may be horizontally spaced apart from each other within the second semiconductor substrate 210B. The second through electrodes 230B may be spaced apart from each other in the second direction D2 and may be electrically connected to the second circuit layer 220B. The second through electrodes 230B may include metal (e.g., copper, tungsten, titanium, tantalum, etc.).

The third chip pads 240B may be disposed on the fourth surface 200Bb of the second semiconductor chip 200B and may be electrically connected to the second circuit layer 220B. The second bumps 250B may be respectively disposed on the third chip pads 240B and may be respectively connected to the third chip pads 240B. The fourth chip pads 260B may be disposed on the third surface 200Ba of the second semiconductor chip 200B and may be respectively connected to the second through electrodes 230B. The third and fourth chip pads 240B and 260B may include metal (e.g., copper). The second bumps 250B may include a conductive material and may have a shape of at least one of a solder ball, a bump, and a pillar.

The second conductor patterns 270B may be disposed on the fourth surface 200Bb of the second semiconductor chip 200B. The second conductor patterns 270B may have substantially the same shape as the lower conductor patterns A and B described above with reference to FIGS. 2A to 2C. Although not shown, the second conductor patterns 270B may be electrically connected to external terminals, and a current may be applied to the second conductor patterns 270B. The second conductor patterns 270B may have shapes different from those described above.

The first and second semiconductor chips 200A and 200B may be memory chips. The lower semiconductor chips 100A may be a memory chip, a logic chip, an application processor (AP) chip, or a system on a chip (SOC). The first and second semiconductor chips 200A and 200B and the lower semiconductor chips 100A may be electrically connected to each other and constitute a high bandwidth memory (HBM) chip.

Referring to FIG. 7B, the first surfaces 200Aa of the first semiconductor chips 200A and the fourth surfaces 200Bb of the second semiconductor chips 200B may face each other. A current may be applied to the upper conductor patterns 280A and the second conductor patterns 270B to generate a magnetic field, and accordingly, the upper conductor patterns 280A and the second conductor patterns 270B may be aligned with each other in the first direction D1 by magnetic force. When the second conductor patterns 270B are aligned with the upper conductor patterns 280A, the second conductor patterns 270B may be spaced apart from the upper conductor patterns 280A in the first direction D1.

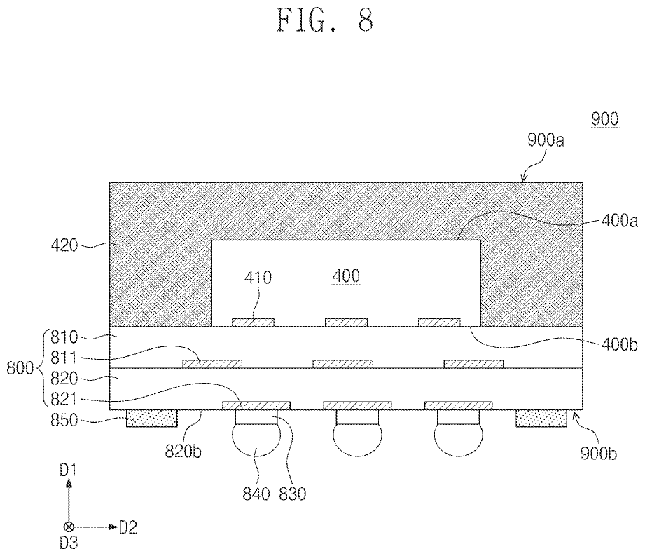

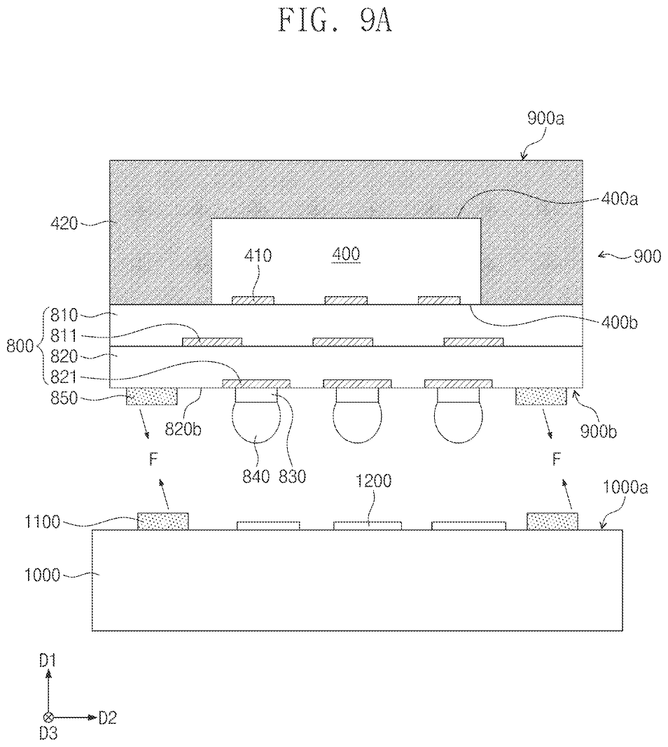

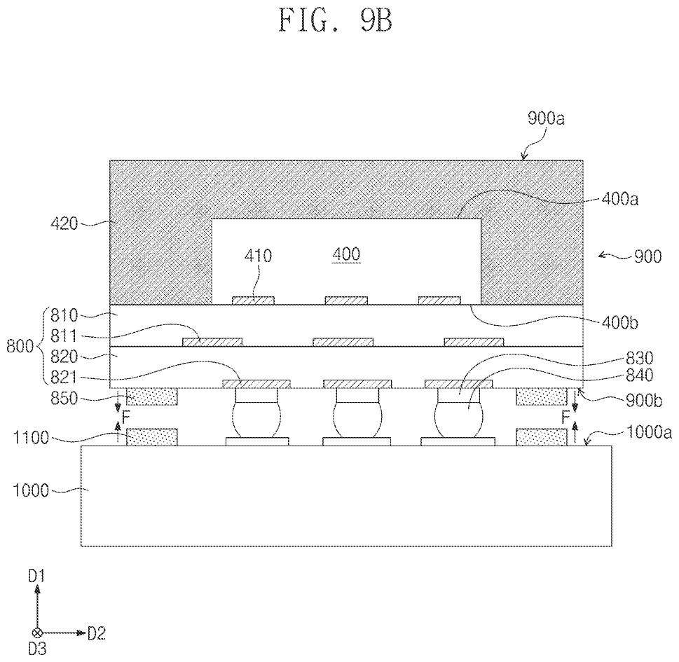

FIG. 8 is a cross-sectional view of a semiconductor package. FIGS. 9A and 9B are cross-sectional views illustrating alignment of a semiconductor package and a lower substrate. Hereinafter, differences from the above description will be mainly described for simplicity of description.

Referring to FIG. 8, a semiconductor structure 900 may include a semiconductor chip 400, a substrate 800, a molding layer 420, bump pads 830, bumps 840, and a conductor pattern 850.

The semiconductor chip 400 may be mounted on an upper surface of the substrate 800. When viewed in a plan view, the semiconductor chip 400 may be disposed on a center of the substrate 800. The semiconductor chip 400 may be a memory chip, a logic chip, an application processor (AP) chip, or a system on a chip (SOC). The substrate 800 may be a redistribution board, a printed circuit board, or an interposer board.

The semiconductor chip 400 may have an upper surface 400a and a lower surface 400b that face each other. The lower surface 400b of the semiconductor chip 400 may be in contact with the substrate 800. The semiconductor chip 400 may include integrated circuits and chip pads 410. The chip pads 410 may be disposed on the lower surface 400b of the semiconductor chip 400 and electrically connected to integrated circuits.

The molding layer 420 may be disposed on the upper surface of the substrate 800 and may cover the upper surface 400a and side surfaces of the semiconductor chip 400. The molding layer 420 may not extend between the substrate 800 and the semiconductor chip 400. The molding layer 420 may include an insulating polymer such as an epoxy-based molding compound.

The substrate 800 may include an insulating layer 810, first pads 811, a protective layer 820 and second pads 821. The insulating layer 810 may be disposed on a lower surface 400b of the semiconductor chip 400 and a lower surface of the molding layer 420. For example, the insulating layer 810 may include an organic material such as a photo-imageable dielectric (PID) material. The photo-imageable dielectric material may include, for example, at least one of photosensitive polyimide, polybenzoxazole, phenol-based polymer, and benzocyclobutene-based polymer. Although the example in FIG. 8 depicts one insulating layer 810, there can be multiple insulating layers 810.

The first pads 811 may be provided in the insulating layer 810. The protective layer 820 may be disposed on a lower surface of the insulating layer 810 to cover the insulating layer 810 and the first pads 811. The protective layer 820 may absorb stress. The stress may be stress due to differences in thermal expansion coefficients of components, but the cause of stress is not limited thereto. The protective layer 820 may include, for example, silicon, a polymer, an adhesive insulating layer, or a photo-imageable dielectric (PID) material. The polymer may be, for example, a polyimide or an epoxy-based polymer. The adhesive insulating layer may include Ajinomoto build-up layer (ABF).

The second pads 821 may be provided in the protective layer 820. Although not shown, the semiconductor chip 400 may be electrically connected to the second pads 821 by a metal wiring in the protective layer 820 and the insulating layer 810.

The bump pads 830 may be provided on a lower surface 820b of the protective layer 820. The bump pads 830 may be electrically connected to the second pads 821, respectively. The bumps 840 may be respectively disposed on the bump pads 830. The bumps 840 may include a conductive material and may have a shape of at least one of a solder ball, a bump, and a pillar.

The first pads 811, the second pads 821, and the bump pads 830 may include metal (e.g., copper).

The conductor patterns 850 may be disposed on a lower surface 820b of the protective layer 820. The conductor patterns 850 may have substantially the same shape as the lower conductor patterns A and B described with reference to FIGS. 2A to 2C. Although not shown, the conductor pattern 850 may be electrically connected to external terminals and a current may be applied to the conductor pattern 850. The conductor pattern 850 may have a shape different from that described above.

Referring to FIGS. 9A and 9B, a semiconductor structure 900 may be stacked on an upper surface 1000a of a lower substrate 1000 in a first direction D1 perpendicular to the upper surface 1000a of the lower substrate 1000. The semiconductor structure 900 may have an upper surface 900a and a lower surface 900b that face each other, and the lower surface 900b of the semiconductor structure 900 may face the upper surface 1000a of the lower substrate 1000.

As described with reference to FIG. 3, the lower substrate 1000 may include lower conductor patterns 1100 on the upper surface 1000a of the lower substrate 1000. A current may be applied to the lower conductor patterns 1100 and the conductor patterns 850 to generate a magnetic field, and accordingly, the lower conductor patterns 1100 and the conductor patterns 850 may be aligned with each other in the first direction D1 by magnetic force. When the conductor patterns 850 are aligned with the lower conductor patterns 1100, the conductor patterns 850 may be spaced apart from the lower conductor patterns 1100 in the first direction D1.

In some implementations, the current may be applied through the conductor pattern formed on the semiconductor device or the substrate to generate the magnetic field, and semiconductor device or the substrate may be self-aligned due to attraction by the magnetic field. The conductor pattern may be provided on the lower substrate and/or the semiconductor chip. The size and spacing of the magnetic field pattern formed depending on the required alignment precision may be designed. The conductor shielding structure may be added to prevent the circuit damage in the device due to the magnetic force.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

While embodiments are described above, a person skilled in the art may understand that many modifications and variations are made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims.

What is claimed is:

1. A stacked structure comprising:
a lower substrate; and
a first semiconductor chip stacked on an upper surface of the lower substrate,
wherein the lower substrate includes a lower conductor pattern disposed on the upper surface of the lower substrate,
wherein the first semiconductor chip has first and second surfaces facing each other,
wherein the second surface of the first semiconductor chip faces the upper surface of the lower substrate,
wherein the first semiconductor chip comprises a first conductor pattern disposed on the second surface and aligned with the lower conductor pattern in a first direction perpendicular to the upper surface of the lower substrate, and
wherein the first conductor pattern is spaced apart from the lower conductor pattern in the first direction.

2. The stacked structure of claim 1, wherein the lower conductor pattern comprises:
a first coil pad and a second coil pad horizontally spaced apart from each other; and
a line portion connecting the first coil pad and the second coil pad, and
wherein the line portion has a coil shape surrounding the second coil pad.

3. The stacked structure of claim 1, wherein the lower conductor pattern comprises:
a first pad portion and a second pad portion that are spaced apart from each other in a second direction parallel to the upper surface of the lower substrate; and
a line portion extending in the second direction between the first pad portion and the second pad portion, and
wherein the line portion extends in a zigzag shape in a third direction parallel to the upper surface of the lower substrate and intersecting the second direction.

4. The stacked structure of claim 3, wherein the line portion has first and second side surfaces facing each other in the third direction,
wherein the line portion defines a first hole, a second hole, third holes, and fourth holes,
wherein the first hole and the third holes extend through the line portion and have a bar shape extending in the third direction from the second side surface of the line portion,
wherein the second holes and the fourth hole extend through the line portion and have a bar shape extending in a direction opposite to the third direction from the first side surface of the line portion, and
wherein the second holes and the third holes are alternately disposed in the second direction.

5. The stacked structure of claim 4, wherein the second holes have a first portion and a second portion,
wherein the third holes have a third portion and a fourth portion,
wherein the first to fourth portions have a first to fourth width in the second direction, respectively, and
wherein the first width is smaller than the second width, and the third width is larger than the fourth width.

6. The stacked structure of claim 5, wherein the second width and the third width increase in the second direction.

7. The stacked structure of claim 1, wherein the lower substrate comprises:
a redistribution insulation layer;
redistribution patterns disposed in the redistribution insulating layer;
first redistribution pads respectively connected to the redistribution patterns;
second redistribution pads respectively connected to the redistribution patterns; and
redistribution bumps respectively disposed on the second redistribution pads.

8. The stacked structure of claim 1, wherein the lower substrate comprises:
a first base substrate;
a wiring layer on the first base substrate;
a plurality of through electrodes penetrating the first base substrate;
second substrate pads respectively connected to the plurality of through electrodes; and
first base bumps respectively disposed on the second substrate pads.

9. The stacked structure of claim 1, wherein the lower substrate comprises:
a second base substrate;
third substrate pads disposed on a lower surface of the second base substrate; and
second base bumps respectively disposed on the third substrate pads.

10. The stacked structure of claim 1, wherein the first semiconductor chip comprises:
a first semiconductor substrate;
second chip pads disposed on an upper surface of the first semiconductor chip;
first through electrodes penetrating the first semiconductor substrate and respectively connected to the second chip pads; and
a first circuit layer disposed on a lower surface of the first semiconductor substrate and comprising a first sub-circuit layer and a second sub-circuit layer, and
wherein the stacked structure further comprises a sub-conductor pattern disposed on a lower surface of the first sub-circuit layer.

11. The stacked structure of claim 1, wherein the first semiconductor chip comprises:
a first semiconductor substrate;
second chip pads disposed on an upper surface of the first semiconductor chip;
first through electrodes penetrating the first semiconductor substrate and respectively connected to the second chip pads;
an interlayer circuit layer disposed on a lower surface of the first semiconductor substrate; and
a first circuit layer disposed on a lower surface of the interlayer circuit layer, and
wherein a shielding layer is interposed between the interlayer circuit layer and the first circuit layer.

12. The stacked structure of claim 10, further comprising:
an interlayer circuit layer interposed between the first semiconductor substrate and the first circuit layer; and
a shielding layer interposed between the interlayer circuit layer and the first circuit layer.

13. The stacked structure of claim 1, further comprising a second semiconductor chip having a third surface and a fourth surface that face each other and stacked on the first semiconductor chip,
wherein the first semiconductor chip comprises an upper conductor pattern on the first surface,
wherein the fourth surface of the second semiconductor chip faces the first surface of the first semiconductor chip,
wherein the second semiconductor chip comprises a second conductor pattern disposed on the fourth surface,
wherein the second conductor pattern is aligned with the upper conductor pattern in the first direction, and
wherein the second conductor pattern is spaced apart from the upper conductor pattern in the first direction.

14. A stacked structure comprising:
a lower semiconductor chip; and
a first semiconductor chip stacked on an upper surface of the lower semiconductor chip,
wherein the lower semiconductor chip includes a lower conductor pattern disposed on the upper surface;
wherein the first semiconductor chip has first and second surfaces facing each other,
wherein the second surface of the first semiconductor chip faces the upper surface of the lower semiconductor chip,
wherein the first semiconductor chip comprises:
a first semiconductor substrate;
second chip pads disposed on a first surface of the first semiconductor substrate;
first through electrodes penetrating the first semiconductor substrate and respectively connected to the second chip pads;
a first circuit layer disposed on a lower surface of the first semiconductor substrate;
a first conductor pattern and first chip pads disposed on the second surface of the first semiconductor chip; and
first bumps respectively disposed on the first chip pads,
wherein the first conductor pattern is aligned with the lower conductor pattern in a first direction perpendicular to the upper surface of the lower semiconductor chip,
wherein the first conductor pattern is spaced apart from the lower conductor pattern in the first direction, and wherein the lower semiconductor chip and the first semiconductor chip are connected to each other through the first bumps.

15. The stacked structure of claim 14, wherein the lower conductor pattern comprises:
a first coil pad and a second coil pad horizontally spaced apart from each other; and
a line portion connecting the first coil pad and the second coil pad, and
wherein the line portion has a coil shape surrounding the second coil pad.

16. The stacked structure of claim 14, wherein the lower conductor pattern comprises:
a first pad portion and a second pad portion that are spaced apart from each other in a second direction parallel to the upper surface of the lower semiconductor chip; and
a line portion extending in the second direction between the first pad portion and the second pad portion, and
wherein the line portion extends in a zigzag shape in a third direction parallel to the upper surface of the lower semiconductor chip and intersecting the second direction.

17. The stacked structure of claim 16, wherein the line portion has first and second side surfaces facing each other in the third direction,
wherein the line portion defines a first hole, a second hole, third holes, and fourth holes
wherein the first hole and the third holes extend through the line portion and have a bar shape extending in the third direction from the second side surface of the line portion; and
wherein the second holes and the fourth hole extend through the line portion and have a bar shape extending in a direction opposite to the third direction from the first side surface of the line portion, and
wherein the second holes and the third holes are alternately disposed in the second direction.

18. The stacked structure of claim 17, wherein the second holes have a first portion and a second portion, the third holes have a third portion and a fourth portion,
wherein the first to fourth portions each have a first to fourth width in the second direction, and
wherein the first width is smaller than the second width, and the third width is larger than the fourth width.

19. The stacked structure of claim 18, wherein the second width and the third width increase in the second direction.

20. A stacked structure comprising:
a lower substrate comprising a lower conductor pattern disposed on an upper surface of the lower substrate; and
a semiconductor structure stacked on the upper surface of the lower substrate,
wherein the semiconductor structure has upper and lower surfaces facing each other, the lower surface of the semiconductor structure faces the upper surface of the lower substrate,
wherein the semiconductor structure comprises a conductor pattern disposed on the lower surface,
wherein the conductor pattern is aligned with the lower conductor pattern in a first direction perpendicular to the upper surface of the lower substrate,
wherein the conductor pattern is spaced apart from the lower conductor pattern in the first direction,
wherein the conductor pattern comprises:
a first coil pad and a second coil pad horizontally spaced apart from each other; and
a line portion connecting the first coil pad and the second coil pad,
wherein the line portion has a coil shape surrounding the second coil pad, and
wherein the semiconductor structure is a semiconductor package or a semiconductor chip.
